(19) United States
(12) Patent Application Publication
(10) Pub. No.: US 2013/0244447 A1
(43) Pub. Date: Sep. 19, 2013

(54) OXIDATION OF METALLIC FILMS

(71) Applicants: Auxence Minko, Winnipeg (CA); Douglas A. Buchanan, Winnipeg (CA)

(72) Inventors: Auxence Minko, Winnipeg (CA); Douglas A. Buchanan, Winnipeg (CA)

(73) Assignee: UNIVERSITY OF MANITOBA, Winnipeg (CA)

(21) Appl. No.: 13/636,085

(22) PCT Filed: Nov. 24, 2011
(86) PCT No.: PCT/CA2011/050729

§ 371 Date: Sep. 19, 2012

(51) Int. Cl. H01L 21/02

(52) U.S. Cl. CPC H01L 21/02181
USPC 438/785

(57) ABSTRACT

Methods for the aqueous oxidation of metallic films are described. For example, a film of hafnium metal on a silicon substrate can be oxidized to hafnium dioxide using hot deionized water. Methods for fabricating electrical components such as capacitors and field effect transistors using the oxidized metallic films are also described. For example, capacitors having a hafnium dioxide dielectric layer can be fabricated.

### BACKGROUND

Silicon dioxide is a common insulating layer used as the gate dielectric in field effect transistors; however, the continuous scaling-down of silicon integrated circuits has led to silicon dioxide films that are only a few atoms thick. At this thickness, the insulating properties of a film may be lost. In fact, at a size below 15 Å, the leakage current due to direct tunneling may exceed the acceptable limits of about 1 A/cm².

A metallic or metal containing film may be deposited on a substrate. Common methods for depositing a metallic or metal containing film include vapor deposition, plasma spray processes and sputtering. Vapor deposition processes provide a metallic or metal containing film on a substrate utilizing the material for deposition in a suitable atmosphere, such as a vacuum or an inert shielding gas, wherein the material is heated until it evaporates and is deposited on a substrate. Plasma spray processes provide a metallic or metal containing film on a substrate utilizing the material to be deposited in the form of a fine-grained powder which is brought into a plasma arc so that the particles melt and are deposited on a substrate. Cathodic magnetron sputtering or radio-frequency ionic sputtering provide a metallic or a metal containing film on a substrate utilizing the material to be deposited as a metallic target in a gas discharge; wherein the material is sputtered by ion bombardment and metallic particles are removed from the target being deposited on the substrate. The target becomes the cathode and the anode is located beneath the substrate. Gases and other volatile compounds may be introduced into the deposition chamber and incorporated into the deposited metallic or a metal containing film.

Substrates may undergo one or more cleaning or preparation cycles before deposition of a metallic or metal containing film. Common methods of cleaning and preparing substrates include the RCA method, piranha washes, hydrogen fluoride washes, and hydrochloric acid washes. The RCA method comprises a two-stage cleaning process using (1) a high-pH alkaline liquid mixture (SC-1) based on ammonia water, hydrogen peroxide and deionized (DI) water, and (2) a low-pH acidic liquid mixture (SC-2) comprising hydrochloric acid, hydrogen peroxide and DI water. Piranha solutions, also known as piranha etches, may be acidic or basic. “Acidic piranha” is a mixture of sulfuric acid (H₂SO₄) and hydrogen peroxide (H₂O₂). Because this mixture is a strong oxidizer, it will remove most organic matter, and it will also hydroxylate most surfaces, making them hydrophilic. “Basic piranha” is about a 3:1 volume ratio of ammonium hydroxide (NH₄OH) with hydrogen peroxide. Hydrogen fluoride (HF) is often used in about a 1% buffered solution to remove silicon dioxide from silicon substrates. Hydrochloric acid (HCl) is often used in a 1% solution may be used to remove metal contaminants.

### SUMMARY

This disclosure is not limited to the particular systems, devices and methods described, as these may vary. The terminology used in the description is for the purpose of describing the particular versions or embodiments only, and is not intended to limit the scope. While various compositions and methods are described in terms of “comprising” various components or steps (interpreted as meaning “including, but not limited to”), the compositions and methods can also “consist essentially of” or “consist of” the various components and steps, and such terminology should be interpreted as defining essentially closed-member groups.

Methods describe novel and simple processes comprising, among other things, the oxidation of hafnium metal, in some embodiments leading to the fabrication of a dielectric film. The use of hot deionized water in some embodiments may be used to fabricate high quality hafnium dioxide, and may reduce its defects.

In an embodiment, a method of producing a metal oxide, metal oxynitride, or metal silicate film may include oxidizing a metal, metal nitride, or binary metal-silicon film by contacting the metal, metal nitride, or binary metal-silicon film with at least one oxidant to provide the metal oxide, metal oxynitride, or metal silicate film; wherein the metal oxide, metal oxynitride, or metal silicate film may have a defect density less than about 10¹¹ cm⁻².

In an embodiment, a method of producing an electronic element may include depositing a metal, metal nitride, or binary metal-silicon film on a substrate; oxidizing the metal, metal nitride, or binary metal-silicon film by contacting the metal, metal nitride, or binary metal-silicon film with at least one oxidant to provide a metal oxide, metal oxynitride, or metal silicate dielectric layer; and coating the metal oxide, metal oxynitride, or metal silicate dielectric layer with a conductive material, wherein the metal oxide, metal oxynitride, or metal silicate dielectric layer may have a defect density less than about 10¹¹ cm⁻².

In an embodiment, a method of producing a dielectric film may comprise oxidizing a metal, metal nitride, or binary metal-silicon film by contacting the metal, metal nitride, or binary metal-silicon film; wherein the dielectric film may have a defect density less than about 10¹¹ cm⁻², and may have a relative dielectric constant greater than about 3.9.

In an embodiment, a film may include one or more strata; wherein each of the one or more strata may comprise at least one metal oxide, metal oxynitride or metal silicate, and each of the one or more strata may have a defect density less than about 10¹¹ cm⁻².

In an embodiment, an electronic element may comprise one or more dielectric layers on a substrate; wherein each of the one or more dielectric layers comprises at least one metal oxide, metal oxynitride or metal silicate and may have a low defect density.

In an embodiment, a film may include one or more strata; wherein each of the one or more strata may have a defect density less than about 10¹¹ cm⁻² and may be separated from a substrate by a minimized interfacial layer.

In an embodiment, a dielectric film may include one or more strata; wherein each of the one or more strata has a defect density less than about 10¹¹ cm⁻² and may have a relative dielectric constant greater than about 3.9.

### BRIEF DESCRIPTION OF THE DRAWINGS

FIG. 1 is a flowchart that illustrates an exemplary method for fabricating an electronic element, in accordance with an embodiment.

FIG. 2 is a plot that illustrates the high frequency capacitance-voltage (HFCV) characteristics of a 1×10⁻⁴ cm² capacitor, in accordance with an embodiment. 1×10⁻⁴ cm² capacitor. The device was swept twice at the rate of 0.27 V/s from inversion to accumulation with 10 sec delay in accumulation. The inset curves show the low level of hysteresis.

FIG. 3 is a plot that illustrates the capacitance-voltage characteristics of multiple capacitors, in accordance with an embodiment. The C-V curves were measured at 100 kHz and normalized to area. No significant effect is observed. The slight difference arises from small lithographic variances.

FIG. 4 is a plot that illustrates the frequency dependent capacitance-voltage characteristics of a capacitor, in accordance with an embodiment. Frequency dispersion measurements of a 1×10⁻⁴ cm² capacitor were taken at 1, 10, and 100 kHz with an AC signal peak-to-peak voltage of 30 mV.

FIG. 5 is a plot that illustrates the leakage current characteristics of a capacitor, in accordance with an embodiment. The leakage current density of a 1×10⁻⁴ cm² capacitor is in the same order of magnitude of silicon dioxide for similar equivalent oxide thickness (EOT).

FIG. 6 is a plot that illustrates the capacitance-voltage characteristics of a stressed capacitor, in accordance with an embodiment. HFCV response of a 1×10⁻⁴ cm² capacitor stressed at 2 V. The small C-V shift indicates the presence of small defect density of approximately 10¹¹ cm⁻².

### DETAILED DESCRIPTION

Materials with dielectric constants greater than that of silicon dioxide (k=3.9), so-called “high-K” materials, may allow the use of thicker gate dielectrics and retention of the required insulating properties. A promising high-K material for use in gate dielectrics is hafnium dioxide; however, the deposition process of hafnium dioxide films may lead to a high density of defects in the gate dielectric stack and may lead to the formation of an interfacial silicon dioxide layer which could negate the effect of using a high-k dielectric.

Capacitance of a gate dielectric may be used to control current flow in a field effect transistor. For two parallel plates separated by a dielectric, capacitance is given by:

$$C = \frac{k {ɛ}_{0} A}{t} \qquad ( 1 )$$

where, k is the dielectric constant of dielectric (may also be called εᵣ for relative permittivity), ε₀ is the electric constant equal to about 8.854×10⁻¹² F·m⁻¹, A is the area of overlap for the two plates, and t is the thickness of the dielectric. When the area is scaled down to create smaller components, the thickness may also be diminished to maintain a given capacitance; however, when the gate dielectric is too thin it may allow an unacceptable amount of leak voltage. Silicon dioxide has a k value of about 3.9. If a high-k material replaced silicon dioxide, then the same capacitance per area could be achieved with a physically thicker dielectric film and potentially lower leakage.

The concept of equivalent oxide thickness (EOT) allows comparison of films with differing k values and the determination of the thickness that would result in the same capacitance. EOT is given by:

$$EOT = {t}_{{sio}_{2}} + {t}_{high - k} \frac{{k}_{{sio}_{2}}}{{k}_{high - k}}$$

where t_{SiO}_{₂} is the physical thickness of the eventual interfacial silicon dioxide layer (k_{SiO}_{₂}=3.9) and t_{high-k} is the physical thickness of the high-k layer with dielectric constant k_{high-k}. Lower EOT (i.e. higher capacitance) values may be achieved by combining higher k_{high-k} values together with thinner t_{SiO}_{₂} layers. The EOT may be determined from the fitting of the experimental capacitance-voltage trace. For a given set of samples with identical characteristics (processing conditions, gate material, post-deposition annealing, etc.) and different t_{high-k}, the t_{SiO}_{₂} and k_{high-k} can be determined by plotting the EOT vs t_{high-k} and assuming a linear relationship as in Equation (2).

In some embodiments, multiple metallic or metal containing films may be deposited onto a substrate as a plurality of strata. In such embodiments a lower strata may improve the physical properties of an upper strata, or vice versa. In other embodiments, a metallic or metal containing film may be deposited onto a substrate as a single stratum. In some embodiments, the metallic or metal containing film may be essentially free of oxygen. In some embodiments, a metallic or metal containing film may be deposited onto a substrate by sputtering.

In embodiments, a metallic or metal containing film may be deposited onto a substrate selected from, but not limited to, glass, ceramic, plastic, metal, textile, semiconductor, carbonaceous materials, and combinations thereof. In some embodiments, a metallic or metal containing film may be deposited onto a substrate comprising a semiconductor. In these embodiments the semiconductor may comprise, n-type silicon, p-type silicon, germanium, silicon carbide, gallium arsenide, aluminum gallium arsenide, indium gallium arsenide, indium phosphide, indium gallium phosphate.

In embodiments, a metallic or metal containing film may be selected from, but not limited to, a metal film, a metal nitride film, or a binary metal-silicon film. In some embodiments, the metallic or metal containing film may be essentially free of oxygen. In embodiments, the metallic or metal containing film may be in direct contact with the substrate or may be separated from the substrate by an interfacial layer. In some embodiments, the interfacial layer may be minimized. In embodiments wherein the substrate is silicon, the interfacial layer may be silicon dioxide.

In embodiments, a metallic or metal containing film may be of any thickness known in the art. In some embodiments, a metallic or metal containing film may comprise a single atomic layer. In other embodiments, the thickness of a metallic or metal containing film may be about 0.15 nm to about 500 nm, about 0.5 nm to about 200 nm, about 1 nm to about 50 nm, 2 nm to about 10 nm, or any thickness or range of thicknesses between those listed.

In embodiments, a metallic or metal containing film may be oxidized by contacting the metallic or metal containing film with at least one suitable oxidant. In embodiments, the oxidant may be aqueous. The aqueous oxidant may comprise water, deionized water, hydrogen peroxide, deionized water with dissolved oxygen or dissolved ozone, or combinations thereof. In some embodiments, the oxidant may be deionized water. The oxidant may comprise other suitable compounds. In some embodiments contacting the metallic or metal containing film with a suitable oxidant may occur at a temperature or range of temperatures of about 50° C. to about 100° C. In embodiments, the contacting may be performed for a length of time sufficient to oxidize the metallic or metal containing film. In some embodiments, the contacting can be performed for various lengths of time, such as about 30 minutes to about 240 minutes.

In some embodiments, a metal, metal nitride, or binary metal-silicon film on a substrate is oxidized by contacting the metal, metal nitride, or binary metal-silicon film with at least one oxidant to provide a metal oxide, metal oxynitride, or metal silicate film on a substrate. In such embodiments, the metal oxide, metal oxynitride, or metal silicate film may have a defect density less than about 10¹² cm⁻², and may be separated from the substrate by a minimized interfacial layer. In some embodiments, the metal oxide, metal oxynitride, or metal silicate film may have a defect density less than about 10¹¹ cm⁻². The metal, metal nitride, or binary metal-silicon film may comprise a metal selected from, but not limited to, strontium, barium, titanium, zirconium, hafnium, niobium, tantalum, aluminum, yttrium, lanthanum, aluminum, gadolinium, ytterbium, dysprosium, niobium, praseodymium, beryllium, magnesium, molybdenum, cadmium, scandium, vanadium chromium, manganese, cobalt, nickel, copper yttrium, ruthenium, rhodium, palladium, tungsten, rhenium, osmium, iridium, gallium, indium and cerium, or a combination thereof. In some embodiments, the metal oxide, metal oxynitride, or metal silicate film may comprise, consist essentially of, or consist of hafnium dioxide. In embodiments, the oxidant may be aqueous. The aqueous oxidant may comprise water, deionized water, hydrogen peroxide, deionized water with dissolved oxygen or dissolved ozone, or combinations thereof. In some embodiments, the oxidant may be deionized water. The oxidant may comprise other suitable compounds. In some embodiments contacting the metal, metal nitride, or binary metal-silicon film with a suitable oxidant may occur at a temperature or range of temperatures of about 50° C. to about 100° C. In embodiments, the contacting may be performed for a length of time sufficient to oxidize the metal, metal nitride, or binary metal-silicon film. The contacting can be performed for various lengths of time, such as about 30 minutes to about 240 minutes. In some embodiments, the metal oxide, metal oxynitride, or metal silicate film may be dried with an inert gas. The metal oxide, metal oxynitride, or metal silicate film may have a relative dielectric constant greater than about 3.9. In some embodiments, the metal oxide, metal oxynitride, or metal silicate film may have a relative dielectric constant greater than about 20.

In some embodiments, hafnium metal is oxidized by contacting the hafnium metal with deionized water to provide hafnium dioxide. In some embodiments contacting hafnium metal with deionized water may occur at a temperature or range of temperatures of about 50° C. to about 100° C. The contacting can be performed for various lengths of time, such as about 30 minutes to about 240 minutes. In such embodiments, the hafnium dioxide may have a defect density less than about 10¹² cm⁻², and may be separated from a substrate by a minimized interfacial layer. In some embodiments, the metal oxide, metal oxynitride, or metal silicate film may have a defect density less than about 10¹¹ cm⁻². In embodiments, hafnium dioxide may be dried, for example, with an inert gas. The hafnium dioxide may have a relative dielectric constant greater than about 3.9. In some embodiments, the hafnium dioxide constant is greater than about 20. In some embodiments, hafnium metal may be present as a film on a substrate to provide hafnium dioxide as a film on a substrate.

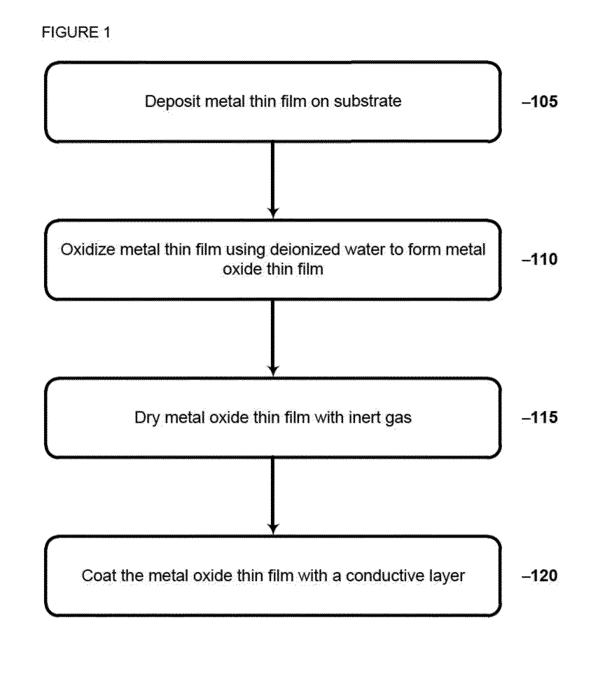

As shown in FIG. 1, an electronic element may be produced by a method comprising: depositing 105 a metal, metal nitride, or binary metal-silicon film on a substrate; oxidizing 110 the metal, metal nitride, or binary metal-silicon film by contacting the metal, metal nitride, or binary metal-silicon film with at least one oxidant to provide a metal oxide, metal oxynitride, or metal silicate dielectric layer; drying 115 the metal oxide, metal oxynitride, or metal silicate dielectric layer with an inert gas; and coating 120 the metal oxide, metal oxynitride, or metal silicate dielectric layer with a conductive material. In such embodiments, the metal oxide, metal oxynitride, or metal silicate dielectric layer may have a defect density less than about 10¹² cm⁻², a minimized interfacial layer, and a leakage current less than that of a silicon dioxide layer of the same equivalent oxide thickness (EOT). In some embodiments, the metal oxide, metal oxynitride, or metal silicate film may have a defect density less than about 10¹¹ cm⁻². The metal, metal nitride, or binary metal-silicon film may comprise a metal selected from, but not limited to, strontium, barium, titanium, zirconium, hafnium, niobium, tantalum, aluminum, yttrium, lanthanum, aluminum, gadolinium, ytterbium, dysprosium, niobium, praseodymium, beryllium, magnesium, molybdenum, cadmium, scandium, vanadium chromium, manganese, cobalt, nickel, copper yttrium, ruthenium, rhodium, palladium, tungsten, rhenium, osmium, iridium, gallium, indium and cerium, or a combination thereof. In some embodiments, the metal oxide, metal oxynitride, or metal silicate film may comprise, consist essentially of, or consist of hafnium dioxide. In embodiments, the oxidant may be aqueous. An aqueous oxidant may comprise water, deionized water, hydrogen peroxide, deionized water with dissolved oxygen or dissolved ozone, or combinations thereof. In some embodiments, the oxidant may be deionized water. In some embodiments contacting the metal, metal nitride, or binary metal-silicon film with a suitable oxidant may occur at a temperature or range of temperatures of about 50° C. to about 100° C. The contacting can be performed for various lengths of time, such as about 30 minutes to about 240 minutes. In embodiments, the metal oxide, metal oxynitride, or metal silicate film may be dried, for example, with an inert gas. The metal oxide, metal oxynitride, or metal silicate film may have a relative dielectric constant greater than about 3.9. In some embodiments, the metal oxide, metal oxynitride, or metal silicate film may have a relative dielectric constant greater than about 20. In embodiments, the substrate may comprise a semiconductor. In these embodiments the semiconductor may comprise, n-type silicon, p-type silicon, germanium, silicon carbide, gallium arsenide, aluminum gallium arsenide, indium gallium arsenide, indium phosphide, indium gallium phosphate. In some embodiments, the electronic element may comprise a capacitor or field-effect transistor.

In embodiments, a dielectric film is produced by a method comprising contacting a metal, metal nitride, or binary metal-silicon film with at least one oxidant. In some embodiments, the dielectric film may have a defect density less than about 10¹² cm⁻² and may have a minimized interfacial layer. In some embodiments, the metal oxide, metal oxynitride, or metal silicate film may have a defect density less than about 10¹¹ cm⁻². In embodiments, the dielectric film may have a relative dielectric constant greater than about 3.9. In some embodiments, the dielectric film has a relative dielectric constant greater than about 20. In embodiments, the at least one oxidant may comprise an aqueous solution. The at least one oxidant may comprise water, deionized water, hydrogen peroxide, deionized water with dissolved oxygen or dissolved ozone, or a combination thereof. The oxidant may comprise other suitable compounds. In some embodiments contacting the metal, metal nitride, or binary metal-silicon film with a suitable oxidant may occur at a temperature or range of temperatures of about 50° C. to about 100° C. In embodiments, the contacting may be performed for a length of time sufficient to oxidize the metal, metal nitride, or binary metal-silicon film. The contacting can be performed for various lengths of time, such as about 30 minutes to about 240 minutes. In embodiments, the dielectric film may be dried, for example, with an inert gas. The dielectric film may comprise a metal selected from, but not limited to strontium, barium, titanium, zirconium, hafnium, niobium, tantalum, aluminum, yttrium, lanthanum, aluminum, gadolinium, ytterbium, dysprosium, niobium, praseodymium, beryllium, magnesium, molybdenum, cadmium, scandium, vanadium chromium, manganese, cobalt, nickel, copper yttrium, ruthenium, rhodium, palladium, tungsten, rhenium, osmium, iridium, gallium, indium and cerium, or a combination thereof. In some embodiments, the dielectric film may comprise, consist essentially of, or consist of hafnium dioxide.

In embodiments, a film may include one or more strata; wherein each of the one or more strata may comprise at least one metal oxide, metal oxynitride or metal silicate, and each of the one or more strata may have a defect density less than about 10¹² cm⁻². In some embodiments, the metal oxide, metal oxynitride, or metal silicate film may have a defect density less than about 10¹¹ cm⁻². In embodiments, the at least one metal oxide, metal oxynitride, or metal silicate may have a relative dielectric constant greater than about 3.9. In some embodiments, the at least one metal oxide, metal oxynitride, or metal silicate has a relative dielectric constant greater than about 20. In embodiments, the at least one metal oxide, metal oxynitride, or metal silicate may comprise a metal selected from strontium, barium, titanium, zirconium, hafnium, niobium, tantalum, aluminum, yttrium, lanthanum, aluminum, gadolinium, ytterbium, dysprosium, niobium, praseodymium, beryllium, magnesium, molybdenum, cadmium, scandium, vanadium chromium, manganese, cobalt, nickel, copper yttrium, ruthenium, rhodium, palladium, tungsten, rhenium, osmium, iridium, gallium, indium and cerium, or a combination thereof. In some embodiments, the at least one metal oxide, metal oxynitride, or metal silicate may comprise, consist essentially of, or consist of hafnium dioxide. In some embodiments, the one or more strata may be separated from a substrate by a minimized interfacial layer.

In embodiments, an electronic element may comprise one more dielectric layers on a substrate; wherein each of the one or more dielectric layers may comprise at least one metal oxide, metal oxynitride or metal silicate, and may have a defect density less than about 10¹² cm⁻². In some embodiments, the metal oxide, metal oxynitride, or metal silicate film may have a defect density less than about 10¹¹ cm⁻². In embodiments, the at least one metal oxide, metal oxynitride, or metal silicate may have a relative dielectric constant greater than about 3.9. In some embodiments, the at least one metal oxide, metal oxynitride, or metal silicate may have a relative dielectric constant greater than about 20. In embodiments, the electronic element may be configured as a capacitor or field-effect transistor. In embodiments the one or more dielectric layers may have a leakage current less than that of a silicon dioxide layer of the same equivalent oxide thickness (EOT). In some embodiments, the at least one metal oxide, metal oxynitride or metal silicate may comprise hafnium dioxide; and the substrate may comprise n-type silicon. In embodiments, the one or more dielectric layers may be separated from a substrate by a minimized interfacial layer.

In embodiments, a film may include one or more strata; wherein each of the one or more strata may have a defect density less than about 10¹² cm⁻² and the one or more strata may be separated from a substrate by a minimized interfacial layer. In some embodiments, the metal oxide, metal oxynitride, or metal silicate film may have a defect density less than about 10¹¹ cm². In embodiments, each of the one or more strata may have a relative dielectric constant greater than about 3.9. In some embodiments, each of the one or more strata may have a relative dielectric constant greater than about 20. In some embodiments, the one or more strata may comprise, consist essentially of, or consist of hafnium dioxide.

In embodiments, a dielectric film may include one or more strata; wherein each of the one or more strata may have a defect density less than about 10¹² cm⁻² and may have a relative dielectric constant greater than about 3.9. In some embodiments, the metal oxide, metal oxynitride, or metal silicate film may have a defect density less than about 10¹¹ cm⁻². In some embodiments, each of the one or more strata may have a relative dielectric constant greater than about 20. In some embodiments, the one or more strata may comprise, consist essentially of, or consist of hafnium dioxide. In embodiments, each of the one or more strata may be separated from a substrate by a minimized interfacial layer.

### EXAMPLES

### Example 1

### Oxidation of Hafnium Metal

A n-type Si(100) wafer with the resistivity of 4 W×cm, was cleaned by a conventional (RCA) technique. This was followed by etching the wafers in a buffered HF (1% v/v) solution for 3 minutes. A thin layer of hafnium metal was sputtered onto the silicon wafer with a power density of 1.23 W/cm². Argon was used as sputtering gas. The pressure during the deposition was kept constant at 12 mTorr. After deposition, the sample was oxidized in deionized water at 70° C. for 4 hours. The sample was dried with nitrogen. Using an ESM 300J ellipsometer (A. Woollan Co., Inc.), the thickness (t=4.8 nm) and the refractive index (n=2) were determined.

### Example 2

### Capacitor Fabrication

The hafnium dioxide coated n-type Si(100) wafer from Example 1 was put under 1×10⁻⁶ Torr vacuum, and aluminum metal-gates were deposited onto the wafer by thermal evaporation. After patterning capacitor areas, the samples were annealed at 425° C. in forming gas (5% hydrogen, 95% nitrogen) for 30 minutes.

### Example 3

### Capacitance Measurement

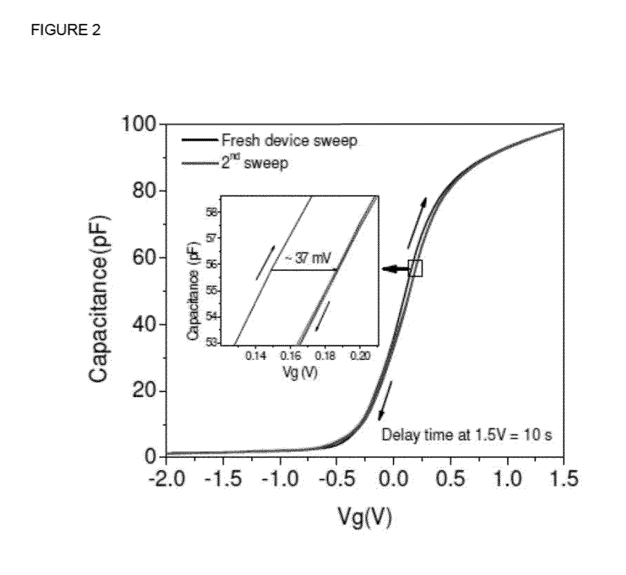

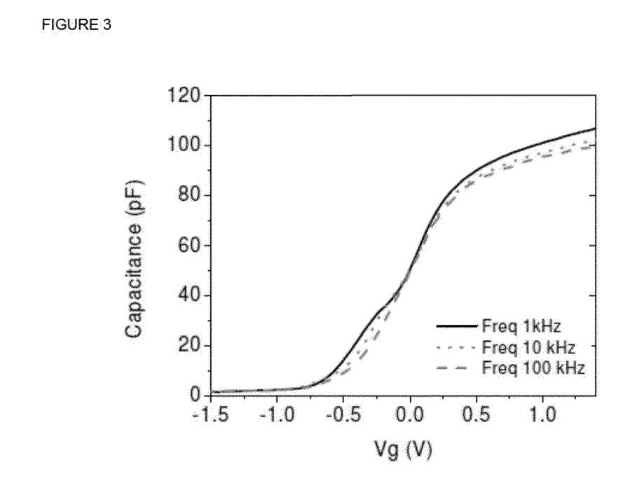

High frequency capacitance-voltage (HFCV) measurements were performed on the capacitors from Example 2 using a HP 4284A Precision LCR (Agilent Technologies, Santa Clara Calif.). As shown in FIG. 2, the HFCV curves shown were measured at 100 kHz, with 30 mV peak-to-peak AC signal, for a 1×10⁻⁴ cm² capacitor where the gate voltage was swept, at a rate of 0.27 V/s, from inversion to accumulation and back into inversion with a holding time of 10 seconds in accumulation. The measurement was repeated once. The measured hysteresis which is 37 mV for the fresh device sweep drops drastically in the second sweep. This can be explained by the filling of the traps close to the interface. The small hysteresis shift is probably the consequence of the low level of mobile charge in the dielectric. In FIG. 3, the capacitance of different capacitors, sized from 1×10⁻⁴ cm² to 2.5×10⁻³ cm², are illustrated. The maximum capacitance values are approximately equal for all areas. The slight differences arise from small lithographic variances. These results indicate the outstanding uniformity of the fabricated film.

### Example 4

### Capacitor Stress and Current-Voltage Measurements

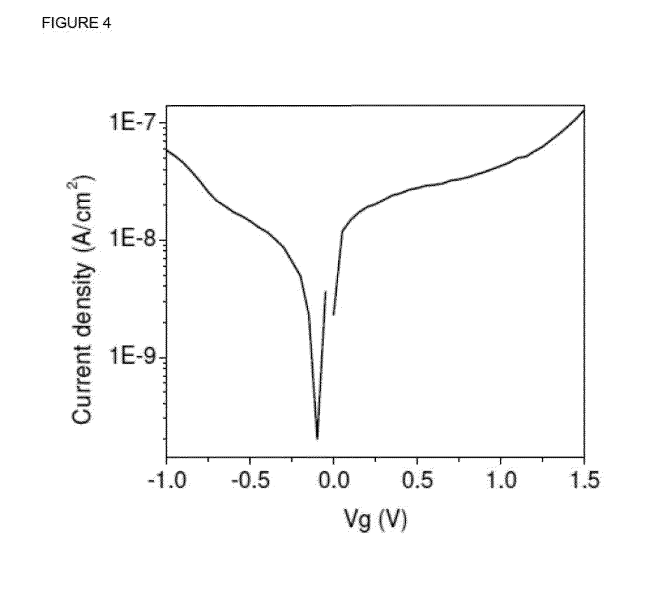

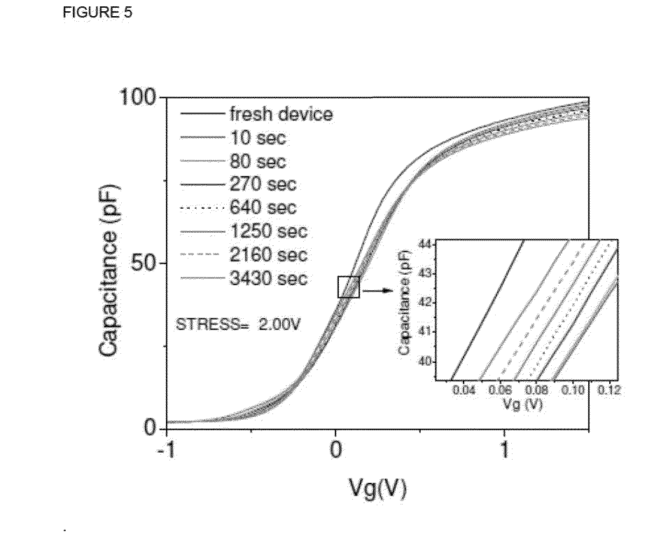

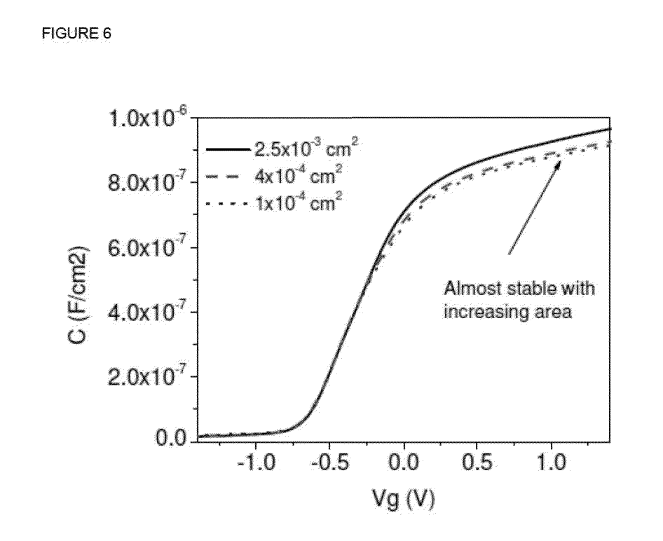

Stress and current-voltage measurements were performed on the capacitors from Example 2 using a Keithley 237 High Voltage Source Measure Unit (Keithley Instruments, Cleveland, Ohio). In FIG. 4, the C-V curves, measured at 1, 10, and 100 kHz with a 30 mV peak-to-peak AC test signal, are displayed. Only a small amount of frequency dispersion can be observed at high frequency. At 1 kHz, the slow states are probably due to the reaction of traps near to the interface at low frequency. The gate leakage current behavior versus gate voltage is shown in FIG. 5. At 1 V, this leakage current density is 4×10⁻⁸ A/cm² which is relatively low when compared to silicon dioxide for the same equivalent oxide thickness (EOT=3.4 nm) at 1 V. In fact, the leakage current for the same silicon dioxide thickness is ˜10⁻⁸ A/cm² at V_{g}=1 V. The measurement of the flat-band voltage shift is taken between stress pulses of 2 V amplitude using the HFCV technique. The stress procedure consists of applying a constant voltage with a duration increasing after each measurement. In FIG. 6, the response of a 1×10⁻⁴ cm² capacitor is shown. The graph displays a maximum shift approximately equals to 30 mV, after more than 2 hours of accumulated stress time. This small shift gives an interesting indication about the low level of charges present in the gate stack. This low level is approximated to 10¹¹ cm⁻², and is one of the lowest ever reported for a hafnium dioxide film.

In the present disclosure, reference is made to the accompanying figures, which form a part hereof. The illustrative embodiments described in the detailed description, figure, and claims are not meant to be limiting. Other embodiments may be used, and other changes may be made, without departing from the spirit or scope of the subject matter presented herein. It will be readily understood that the aspects of the present disclosure, as generally described herein, and illustrated in the figure, may be arranged, substituted, combined, separated, and designed in a wide variety of different configurations, all of which are explicitly contemplated herein.

The present disclosure is not to be limited in terms of the particular embodiments described in this application, which are intended as illustrations of various aspects. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds, compositions or biological systems, which can, of course, vary. It is also to be understood that the terminology used herein is for the purpose of describing particular embodiments only, and is not intended to be limiting.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to embodiments containing only one such recitation, even when the same claim includes the introductory phrases “one or more” or “at least one” and indefinite articles such as “a” or “an” (e.g., “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (e.g., the bare recitation of “two recitations,” without other modifiers, means at least two recitations, or two or more recitations). Furthermore, in those instances where a convention analogous to “at least one of A, B, and C, etc.” is used, in general such a construction is intended in the sense one having skill in the art would understand the convention (e.g., “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or figure, should be understood to contemplate the possibilities of including one of the terms, either of the terms, or both terms. For example, the phrase “A or B” will be understood to include the possibilities of “A” or “B” or “A and B.”

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” and the like include the number recited and refer to ranges which can be subsequently broken down into subranges as discussed above. Finally, as will be understood by one skilled in the art, a range includes each individual member. Thus, for example, a group having 1-3 substituents refers to groups having 1, 2, or 3 substituents. Similarly, a group having 1-5 substituents refers to groups having 1, 2, 3, 4, or 5 substituents, and so forth.

1. A method of producing hafnium dioxide, the method comprising:
oxidizing hafnium metal by contacting the hafnium metal with deionized water to provide the hafnium dioxide.

2. A method of producing a metal oxide, metal oxynitride, or metal silicate film, the method comprising:
oxidizing a metal, metal nitride, or binary metal-silicon film by contacting the metal, metal nitride, or binary metal-silicon film with at least one oxidant to provide the metal oxide, metal oxynitride, or metal silicate film,
wherein the metal oxide, metal oxynitride, or metal silicate film has a defect density less than about 10¹² cm⁻².

3. The method of claim 2, wherein the at least one oxidant is an aqueous solution.

4. The method of claim 2, wherein the at least one oxidant is selected from deionized water, hydrogen peroxide, deionized water with dissolved oxygen or dissolved ozone, and a combination thereof.

5. The method of claim 2, wherein the contacting occurs at a temperature of about 50° C. to about 100° C.

6. (canceled)

7. The method of claim 2, further comprising drying the metal oxide, metal oxynitride, or metal silicate film with an inert gas.

8. The method of claim 2, wherein the metal oxide, metal oxynitride, or metal silicate film has a relative dielectric constant greater than about 3.9.

9.-10. (canceled)

11. The method of claim 2, wherein the metal oxide, metal oxynitride, or metal silicate film comprises hafnium dioxide.

12. The method of claim 2, wherein the metal oxide, metal oxynitride, or metal silicate film is separated from a substrate by a minimized interfacial layer.

13. The method of claim 2, wherein the metal oxide, metal oxynitride, or metal silicate film has a defect density less than about 10¹¹ cm⁻².

14. A method of producing electronic element comprising:
depositing a metal, metal nitride, or binary metal-silicon film on a substrate;
oxidizing the metal, metal nitride, or binary metal-silicon film by contacting the metal, metal nitride, or binary metal-silicon film with at least one oxidant to provide a metal oxide, metal oxynitride, or metal silicate dielectric layer,
wherein the metal oxide, metal oxynitride, or metal silicate dielectric layer has a defect density less than about 10¹² cm⁻²;
drying the metal oxide, metal oxynitride, or metal silicate dielectric layer with an inert gas; and
coating the metal oxide, metal oxynitride, or metal silicate dielectric layer with a conductive material.

15. The method of claim 14, wherein the at least one oxidant is an aqueous solution.

16. The method of claim 14, wherein the at least one oxidant is selected from deionized water, hydrogen peroxide, deionized water with dissolved oxygen or dissolved ozone, and a combination thereof.

17-19. (canceled)

20. The method of claim 14, wherein the metal oxide, metal oxynitride, or metal silicate has a relative dielectric constant greater than about 3.9.

21. (canceled)

22. The method of claim 14, wherein the substrate is a semiconductor.

23. The method of claim 14, wherein the electronic element comprises a capacitor or field-effect transistor.

24.-25. (canceled)

26. The method of claim 14, wherein the metal oxide, metal oxynitride, or metal silicate dielectric layer is separated from a substrate by a minimized interfacial layer.

27. (canceled)

28. The method of claim 14, wherein:
the metal oxide, metal oxynitride, or metal silicate comprises hafnium dioxide; and
the substrate comprises n-type silicon.

29. A method of producing a dielectric film, the method comprising:
oxidizing a metal, metal nitride, or binary metal-silicon film by contacting the metal, metal nitride, or binary metal-silicon film with at least one oxidant to provide the dielectric film,
wherein the dielectric film has a defect density less than about 10¹² cm⁻²,
wherein the dielectric film has a relative dielectric constant greater than about 3.9.

30. The method of claim 29, wherein the at least one oxidant is an aqueous solution.

31-36. (canceled)

37. The method of claim 29, wherein the dielectric film comprises hafnium dioxide.

38. The method of claim 29, wherein the dielectric film is separated from a substrate by a minimized interfacial layer.

39-67. (canceled)
